(19) United States
(12) Patent Application Publication
(10) Pub. No.: US 2011/0135915 A1
(43) Pub. Date: Jun. 9, 2011

(54) Methods of Coating Substrate With Plasma Resistant Coatings and Related Coated Substrates

(75) Inventors: Sang Ho Lee, North Wales, PA (US); Gary Reichl, Coopersburg, PA (US)

(73) Assignee: Greene, Tweed of Delaware, Inc.

(21) Appl. No.: 12/953,224

(22) Filed: Nov. 23, 2010

Related U.S. Application Data
(60) Provisional application No. 61/264,556, filed on Nov. 25, 2009.

(51) Int. Cl. B32B 5/00; C23C 14/30; C23C 14/28; C23C 14/06; C23C 16/22; C23C 14/34; B05D 1/36

(52) U.S. Cl. 428/336; 427/596; 427/595; 427/248.1; 427/255.28; 204/192.1; 427/402

(57) ABSTRACT

The invention includes a method of coating a substrate with a plasma etch-resistant layer that exhibits reduced particulation comprising applying an coating layer to a substrate wherein coating layer has a thickness of about 20 microns or less and wherein the coating layer, after exposure to a fluorine based plasma for an amount of time, is substantially free of any cracks or fissures that span the cross section of the coating layer.

A coated substrate prepared by the methods described. Also included in the invention are coated substrates for use as a structural element in a fluorine-based semiconductor wafer processing protocol, wherein the coating is a coating layer having a thickness of about 20 microns or less and wherein the coating layer, after exposure to a fluorine based plasma for an amount of time, is substantially free of any cracks or fissures that span the cross section of the coating layer and exhibits reduced particulation.

Included are structural elements used in a fluorine-based semiconductor wafer processing protocol, wherein at least a portion of a surface of a structural element is coated with a coating layer that having a thickness of about 20 microns or less and wherein the coating layer, after exposure to a fluorine based plasma for an amount of time, is substantially free of any cracks or fissures that span the cross section of the coating layer and exhibits reduced particulation.

### CROSS REFERENCE TO RELATED APPLICATION

This patent application claims the benefit under 35 U.S.C. §119(e) of U.S. provisional patent application No. 61/264,556, filed Nov. 25, 2009, the disclosure of which is incorporated herein by reference.

### BACKGROUND OF THE INVENTION

Silicon or quartz is widely used for the various component of semiconductor processing equipment. However, these materials are easily etched during plasma etching. Accordingly, as silicon or quartz based material is widely adopted in the plasma etching process, attempts have been made to protect and preserve the silicon or quartz by application of protective coating layers. The aim of such shielding or coating layers is to act to reduce exposure of the quartz or silicon material to various plasmas (NF₃, Cl₂, C₄F₈, CF₄, CHF₃, CH₂F₂, SF₆ and HBr) and thereby prevent or reduce weight loss and/or to reduce particulation during dry etching processes where particles may be dislodged from a chamber wall or from the photoresist materials.

Conventional coatings and methods have been used in an attempt to develop a suitably shielding or protective layer. For example, coatings that contain various ceramic materials such as alumina, aluminum nitride, silicon nitride, silicon carbide, zirconia, yttria-stabilized zirconia, SiAlON, etc., that are known to be chemically stable in plasma etching conditions have been prepared.

A disadvantage of some of these coating materials is that although the weight loss (due to etching) may be reduced, often the coating materials may react with the plasma components and generate unwanted particulates. For example, if silicon or quartz is coated with alumina, the weight loss is reduced since the substrate is protected from the plasma-etching environment. However, in a fluoride-containing etching environment, one finds that alumina from the coating reacts with the fluorine-based plasma and forms aluminum fluoride, a highly stable compound. Because of the stability of aluminum fluoride, it does not evaporate in the chamber and remains in the chamber in the form of particulates, which may contaminate the semiconductor wafers being processed. Therefore, even though aluminum oxide is chemically stable material in plasma etching environment, the particulation issue limits the application.

Some prior art attempts to reduce the particulation problem have been made by coating quartz substrates with yttria. Yttria and alumina interact with plasma etching gases in a similar manner. Yttria is known to be a material that reduces the plasma etching rate and prevents particle generation in semiconductor industry. Therefore, many yttria applications were introduced into the plasma etching related parts. In many cases, bulk yttria was used for parts instead of coatings applied to parts previously fabricated of other materials.

However, the application of bulk yttria has disadvantages: for example, it is expensive and does not have good mechanical strength. In addition most of the bulk yttria cannot be densified to full density causing relatively porous surface of the bulk part from which the fine yttria particles may fall out during plasma etching.

To address the difficulties associated with use of bulk yttira, attempts to use coated yttria parts were made. In many conventional coating applications, thermal spray coating is widely applied, but the thermal spray process gives rise to coating having a porous structure that may cause the yttria particles to fall out during plasma etching. In addition, because of the porosity of the thermal spray coated layer, the layer must be relatively thick to protect the underlying substrates from fluorine-based plasma attack.

Additionally, one compelling disadvantage to the use of these types of yttria coatings is that the coatings tend to separate from the substrate, especially quartz substrate as it has a very low thermal expansion coefficient. Upon exposure to the thermal cycles, the difference in thermal expansion coefficients between that of the coating layer and that of the substrate material is too large and separation or delamination may result. Accordingly, this tendency to delaminate from the substrate makes the use of yttria coatings highly impractical.

However, in view of the advantages afforded by yttria coatings, especially its tendency not to develop particulate contaminates, there remains need in the art for a technical solution that would permit the use of such coatings without significant delamination.

### BRIEF SUMMARY OF THE INVENTION

The invention includes a method of coating a substrate with a plasma etch-resistant layer that exhibits reduced particulation comprising applying an coating layer to a substrate wherein coating layer has a thickness of about 20 microns or less and wherein the coating layer, after exposure to a fluorine based plasma for an amount of time, is substantially free of any cracks or fissures that span the cross section of the coating layer.

Also included is a coated substrate prepared by the methods described. Also included in the invention are coated substrates for use as a structural element in a fluorine-based semiconductor wafer processing protocol, wherein the coating is a coating layer having a thickness of about 20 microns or less and wherein the coating layer, after exposure to a fluorine based plasma for an amount of time, is substantially free of any cracks or fissures that span the cross section of the coating layer and exhibits reduced particulation.

Included are structural elements used in a fluorine-based semiconductor wafer processing protocol, wherein at least a portion of a surface of a structural element is coated with a coating layer that having a thickness of about 20 microns or less and wherein the coating layer, after exposure to a fluorine based plasma for an amount of time, is substantially free of any cracks or fissures that span the cross section of the coating layer and exhibits reduced particulation.

### DESCRIPTION OF THE SEVERAL VIEWS OF THE DRAWINGS

The foregoing summary as well as the following detailed description of preferred embodiments of the invention will be better understood when read in conjunction with the appended drawings. It should be understood that the invention is not limited to the precise arrangements and instrumentalities shown. In the drawings:

FIG. 1 is a schematic electron beam coating chamber assisted by ion beam showing the sample coating;

FIG. 2 shows the microstructure of typical yttria coating by conventional plasma spray coating (left side image) and physical vapor deposition coating by electron beam assisted by ion beam (right side image);

FIG. 3 shows the schematic coating layer design and residual stress with different thermal expansion coefficients;

FIG. 4 shows the schematic coating layer design with buffer layer to reduce the residual stress;

FIG. 5 shows the transparent 5 micron thick yttria coated on quartz substrate

FIG. 6 shows in-line transmittance of 5 micron thick yttria coated on quartz substrate shown in FIG. 5;

FIG. 7 shows a schematic drawing of a poor quality coating layer of a) porous coating and b) cracked coating layer;

FIG. 8 shows a cross section of the yttria coated on quartz before and after plasma etching; and

FIG. 9 shows partially yttria coated silicon before and after plasma etching.

### DETAILED DESCRIPTION OF THE INVENTION

The invention described herein includes methods of coating a substrate with a plasma etch-resistant layer. This coating is unique in that the coating layer is dense and thin compared the currently available yttria coatings, for example, those prepared by thermal spray processes. The coating layer has a thickness of about 20 microns or less and exhibits reduced particulation under plasma etching conditions. Also included are coated substrates made by the method and substrates bearing a coating layer that has a thickness of about 20 microns or less and exhibits reduced particulation and plasma resistance.

The substrate that is coated may be any known in the art. Preferred may be substrate materials that are used to fabricate elements for use in semiconductor wafer processing, such as chamber walls, insulators, electrostatic chucks, windows, showerheads, focus rings, inner rings, outer rings, capture rings, insert rings, screws, bolts, and fasteners, etc.

Examples of substrate materials may include, without limitation, quartz, silicon, alumina, silicon nitride, silicon carbide, zirconia, SiAlON, AlON, aluminum, anodized aluminum, and various kinds of ceramic composites.

The coating layer may be formed of any material capable of exhibiting a level of plasma resistance and/or reduced particulation when exposed to a plasma containing environment, particularly, for example, a fluorine-based plasma containing environment. For example, the coating layer may be formed of yttria or yttria-derived composites for example, yttrium aluminum garnet or yttrium aluminum perovskite or combinations of any of the listed examples. In addition other materials, such as yttrium fluoride, alumina, silicon carbide, aluminum nitride, silicon nitride, silicon carbide, zirconia or yttria-stabilized zirconia may also be included in the invention.

Mechanical and thermal properties, including the thermal expansion coefficients, of exemplary materials for use in the coating layer are set out in Table I:

| | | | | Elastic | | Maximum | Thermal | |
|---|---|---|---|---|---|---|---|---|
| | Density | melting point | Color | Modulus | Hardness | Use Temp | Conductivity | CTE |
| | Units | | | | | | | |
| Material | gm/cc | ° C. | — | GPa | Kg/mm² | ° C. | W/mK | 10⁻⁶/° C. |
| yttria (Y2O3) | 5.03 | 2410 | white | 170 | 600 | 1500 | 14 | 8.1 |
| quartz (SiO2) | 2.20 | 1665 | clear | 73 | 600 | 1100 | 1.38 | 0.55 |
| | | (softening) | | | | | | |
| alumina (Al2O3) | 3.98 | 2050 | ivory | 375 | 1440 | 1200 | 35 | 8.4 |
| silicon (Si) | 2.33 | 1414 | black | 190 | 1150 | | 148 | 2.6 |
| aluminum (Al) | 2.7 | 660 | white | 70 | 17 | | 237 | 23.1 |
| aluminum nitride (AlN) | 3.26 | — | gray | 330 | 1100 | — | 140-180 | 4.5 |
| yttria stabilized zirconia (YSZ) | 6.10 | 2490 | ivory | 200 | 1300 | 1200 | 2 | 10.3 |
| silicon carbide (SiC) | 3.18 | — | black | 410 | 2800 | 1650 | 120 | 4 |
| silicon nitride (Si3N4) | 3.21 | 1900 | grey | 310 | 1450 | 1000 | 30 | 3.3 |
| | | (sublimation) | | | | | | |
| yttrium aluminum garnet | 4.55 | 1970 | clear | 282 | 1350 | 1400 | 13 | 8.2 |
| (YAG) | | | | | | | | |

Such substrate materials may have various thermal expansion coefficients. In some case, the thermal expansion coefficient of coating layer may be larger than the thermal expansion coefficient of substrate. In some case, it may be opposite. When there is a difference in thermal expansion coefficient between the substrate and coating layer, there will be always a residual stress as the coating is performed at elevated temperature. Therefore, the coating layer should be well designed to reduce the residual stress. For example, the substrate may have a low thermal expansion coefficient of about 0.55×10⁻⁶/° C. in case of quartz and the thermal expansion coefficient of yttria coating layer is much higher (8.1×10⁻⁶/° C.), by contrast, the thermal expansion coefficient of aluminum substrate (27×10⁻⁶/° C.) is much greater than the yttria coating layer.

In some circumstances, when the thermal expansion coefficient mismatch between the coating layer material and the substrate is great, for example, a difference of more than 5×10⁻⁶/° C., it may be desirable to lay down an intermediate buffer layer between the substrate and the coating layer. It may be preferred that the buffer layer is made of a material that has a thermal expansion coefficient between the value of the substrate thermal expansion coefficient and the value of the coating layer thermal expansion coefficient, preferably at substantially a mid point between the two values.

In an embodiment, the coating layer has a substantially uniform thickness along the surface of the substrate. It may be preferred that the thickness of the coating layer is about 20 microns or less. Alternatively, the thickness of the coating layer is about 15 microns, or less, about 10 microns or less, about 5 microns or less, and/or about 2 microns or less. In an embodiment, the coating layer has a substantially uniform density along the surface of the substrate. The density of coating may affect the plasma etching resistance. If the coating is not dense enough, the fluorine plasma chemistry will penetrate through the voids in the coating layer and will attack the substrate. Once the coated substrate is attacked, delamination or flaking of coating layer will be observed. The relative density of coating is affected by the relative volume ratio of voids in the coating layer. If the coating is dense, free of voids, the coating density should be the same as the theoretical density of coating material. However, it is not possible to measure the density of coating layer by the Archimedes method. Instead the cross section image by microscope can be a good expression to distinguish the relative coating density. The simple way to quantitatively express the coating density is to measure the in-line transmittance of the coating sample when the substrate is transparent. In some embodiments, the coating layer exhibits an in-line transmittance greater than about 30% at a wavelength greater than about 300 nm.

Alternatively, one may consider the amount of material present in a given volume of space. For example, a coating having density of about 90% means that, per cubic micron, 90% of the volume is occupied by coating material. In an embodiment of the invention, the coating layer has a high density of about 80%, of about 90%, of about 91%, of about 92%, of about 93%, of about 94%, of about 95%, of about 96%, of about 97%, of about 98%, of about 99%, of about 99.1, of about 99.2%, of about 99.3%, of about 99.4%, of about 99.5%, of about 99.6%, of about 99.7%, of about 99.8%, and/or of about 99.9%.

In some embodiments, the coating is substantially gas impermeable.

The coating layer may be applied to the substrate by any means known or to be developed in the art, as long as such application processes permit deposition of a coating of the desired thickness and densities. Suitable application processes may include physical deposition coating and electron beam coating; exemplary processes are set out in detail in, e.g., U.S. Pat. Nos. 6,007,880, 7,205,662 and 7,311,797, the contents of each of which are incorporated herein by reference. Regardless of which method is used, it may be preferred that the coating layer is comparatively dense, gas impermeable layer and/or does not delaminate or flake and also should survive the temperature cycle.

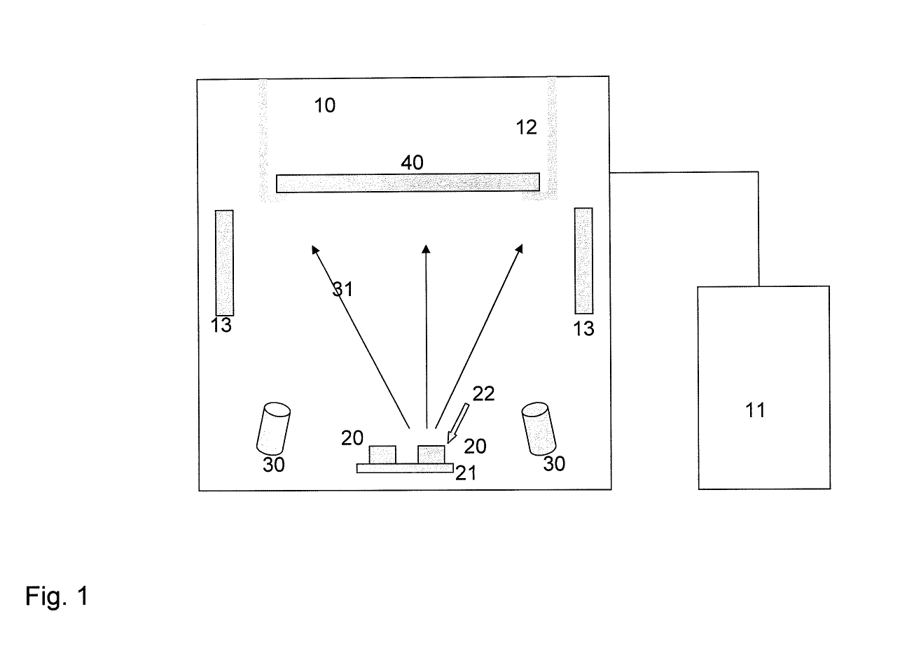

As an example, FIG. 1 is provided, schematically illustrating an electron beam coating chamber assisted by ion beam. The chamber 10 is evacuated by a pump 11 (for example, a diffusion pump, a turbomolecular pump, a molecular drag pump, and/or a cryopump) to keep the high vacuum level. The substrate 40, on which the film deposition takes place is ultrasonically cleaned thoroughly in advance. The substrate 40 is to be held by fixture 12 in the coating chamber. The substrate 40 is preheated by heater 13 to enhance adhesion strength. The coating target material 20 is placed in a crucible 21. For a multiple coating layer design, the crucible is designed to hold up to six different target materials and the crucible can rotate to change the target materials. Electron beam 22 generated from electron gun by anodic arc method melts the target material 20 and evaporates in the chamber as a vapor phase 31. The vapor phase 31 deposits on the surface of substrate 40. In the electron beam coating process, one or two ion sources 30 generated from argon gas are used for substrate etching and cleaning. It is believed that the ion beam assisted coating enhances adhesion strength and increases the density of coating layer.

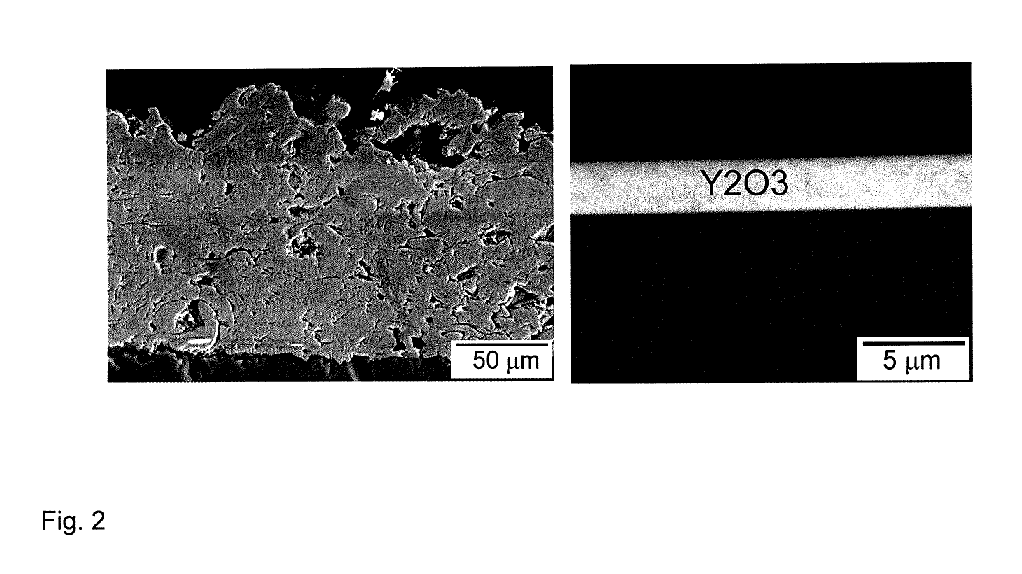

The microstructure of typical yttria coating by conventional thermal spray coating by plasma and physical vapor deposition coating by electron beam assisted by ion beam in this invention can be seen in FIG. 2. While the coating layer of conventional thermal spray coating by plasma is thick and porous (i.e., less dense) as is shown in FIG. 2 (left side image), the coating by electron beam coating is dense as is shown in FIG. 2 (right side image) and therefore, may not need to be thick. Generally the thermal expansion coefficient mismatch between the coating layer material and substrate should not be high. If the mismatch is large, residual stress is built up between the coating layer and substrate and subject to delamination or crack if the coated specimen is exposed to thermal cycle. Theoretically the residual stress between coating layer and substrate is proportional to the coating thickness and mismatch in thermal expansion coefficient. Therefore, it is ideally better to reduce the coating thickness if the coating layer is dense.

In electron beam coating, the higher substrate temperature increases the adhesion strength, but the residual stress may be built up during cooling if the thermal expansion coefficient between the coating layer material and substrate is large. If the coating chamber temperature is decreased to avoid the residual stress, the coating layer can be delaminated if the coated sample is exposed to a thermal cycle. Therefore, careful coating processing parameter should be selected by considering 1) the thermal expansion coefficient mismatch between coating layer and substrate, and 2) coating temperature by considering the adhesion strength and 3) coating thickness. In some embodiments, it may be desirable to carry out the coating process by electron beam coating process at under about 700° C.

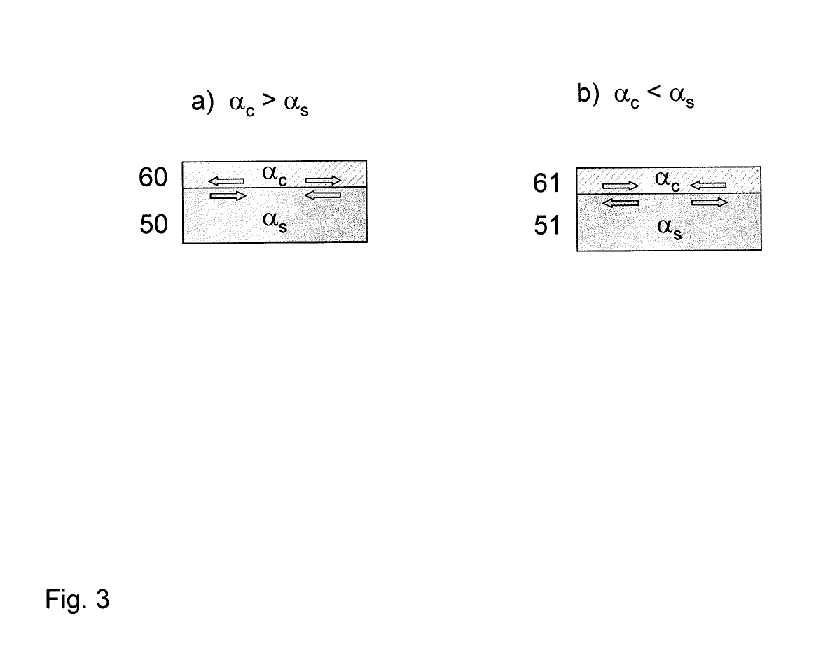

FIG. 3 shows the coating layer configuration with different thermal expansion coefficients. When the thermal expansion coefficient of coating layer is larger than the substrate (for example yttria coating on quartz substrate), the coating layer 60 is going to shrink during cooling stage after the coating. But the substrate 50 would not allow the coating layer 60 to shrink. Therefore tensile stress is built up in the coating layer 60 and compressive stress is built up in the substrate 50. If the residual stress is too large, detrimental fissures or cracks may be observed at the surface of the coating. Such fissures or cracks differ from minor wrinkles (having minimal depth) that may develop shown only at the surface of the coating layer and which are not detrimental. However, if the residual stress is too high, deep cracks may be found in the coating layer. In this case the cracks typically reach the substrate surface. These kinds of cracks should not be generated during coating by adjusting the coating conditions. If the cracks are too deep, the substrate would be etched during plasma etching through the cracks. Therefore, avoidance of the deep cracks is the coating may be important.

On the other hand, if the thermal expansion coefficient of coating layer is smaller than the substrate (for example yttria coating on aluminum substrate), compressive stress is built up in the coating layer 51 and tensile stress is built up in the substrate 61. To reduce the stress, thin coating is preferred. However, just simply reduce the coating thickness would not be able to protect the substrate from the plasma etching.

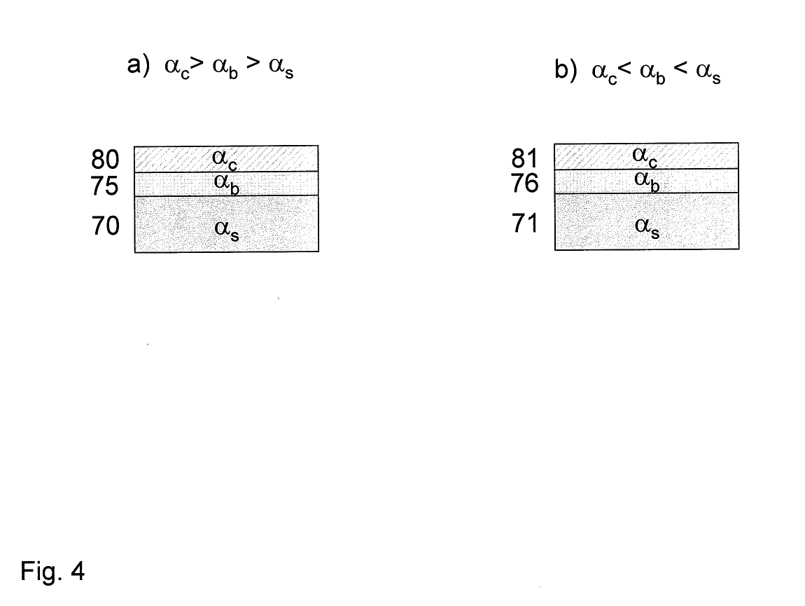

If the mismatch in thermal expansion stress is too high, it is necessary to incorporate the buffer layer to reduce the residual stress as shown in FIG. 4. When the thermal expansion coefficient of coating layer, 80 is larger than substrate 70 (for example yttria coating on quartz substrate), the incorporation of buffer layer 75 would reduce the residual stress. The buffer layer material should have a thermal expansion coefficient between the coating layer 80 and substrate 70. In this case, the silicon material would be a good example to reduce the mismatch in thermal expansion coefficient.

On the other hand, when the thermal expansion of coating layer 81 is smaller than the substrate 71 (for example yttria coating on aluminum), the incorporation of buffer layer 76 would have a thermal expansion coefficient larger than coating layer 81 but smaller than the substrate 71. Some kinds of composite such as Al₂O₃ or ZrO₂ plus fluoride compound such as CaF₂ and YF₃ would be able to adjust the thermal expansion coefficient. Another advantage of CaF₂ and YF₃ is not easily attacked by fluoride based plasma etching.

The coating layer, after being exposes to the plasma etch process, should be substantially free of deep cracks or fissures, when observed, for example, by optical profilometer. For example, after exposure to a fluorine based plasma for an amount of time, the layer is substantially free of any cracks or fissures that span the cross section of the coating layer (that is, from the top surface of the layer to the bottom surface of the layer). In some embodiments, the amount of time is about 1 to about 5 hours, about 1 to about 10 hours, and/or about 1 hour to about 1000 hours. Alternatively or additionally, the amount of time may be up to about 5,000, up to about 7,000 and/or up to about 10,000 hours, depending on the processing conditions applied.

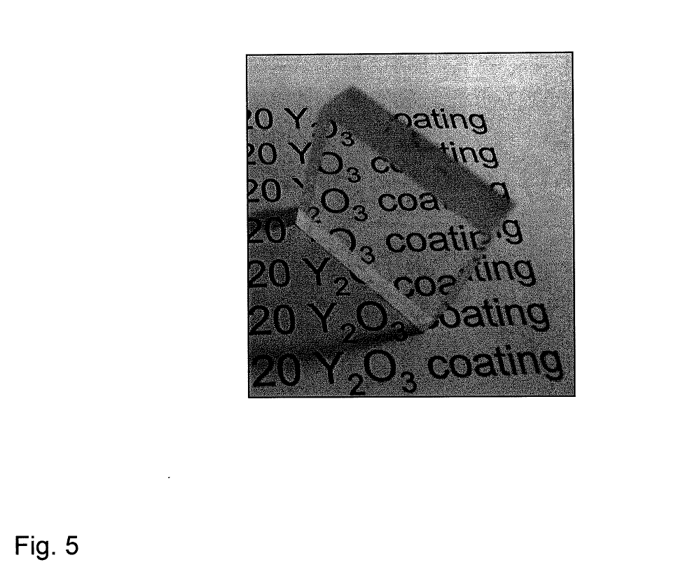

FIG. 5 shows the photograph of 5 micron thick yttria coated on quartz substrate. As the coating layer is very dense, the sample looks transparent. The transmittance is not reduced even after coating compared to quartz substrate because the coating layer is very dense. For this reason, the coating in this invention can be also used for a transparent window material as well.

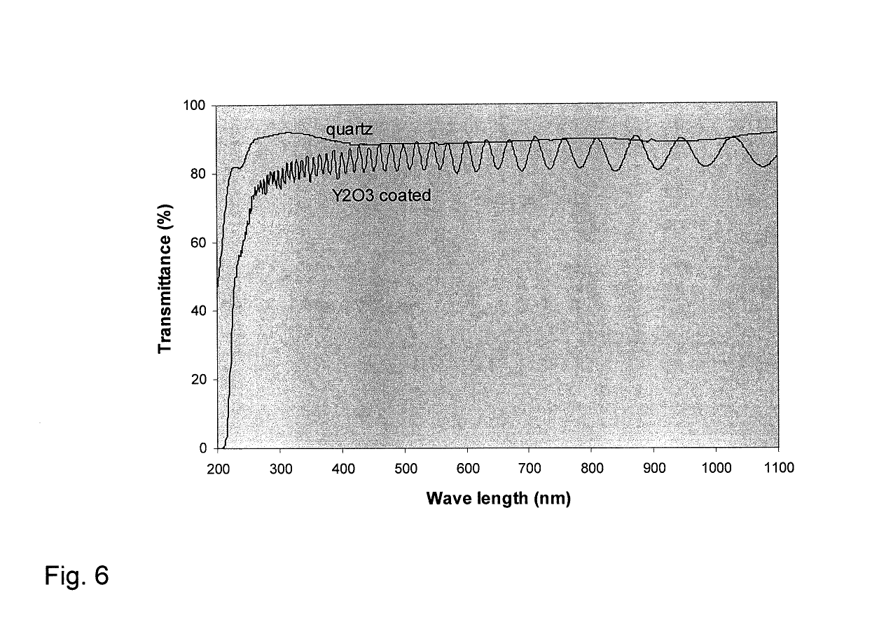

FIG. 6 shows optical transmission of 5 microns thick yttria coated quartz specimen shown in FIG. 5. The transmission shows typical wavy pattern because of the transmittance is affected by the refractive index, extinction coefficient of substrate and coating layer and coating thickness. The coating of the invention shows the in-line transmittance over 80% in visible range. If the coating is porous, the transmittance would not be so high.

As mentioned earlier, the coating layer should be gas impermeable layer and free of deep cracks that reach the substrate. In this case, the substrate will be attacked by plasma etching and the coating layer would delaminate from the substrate.

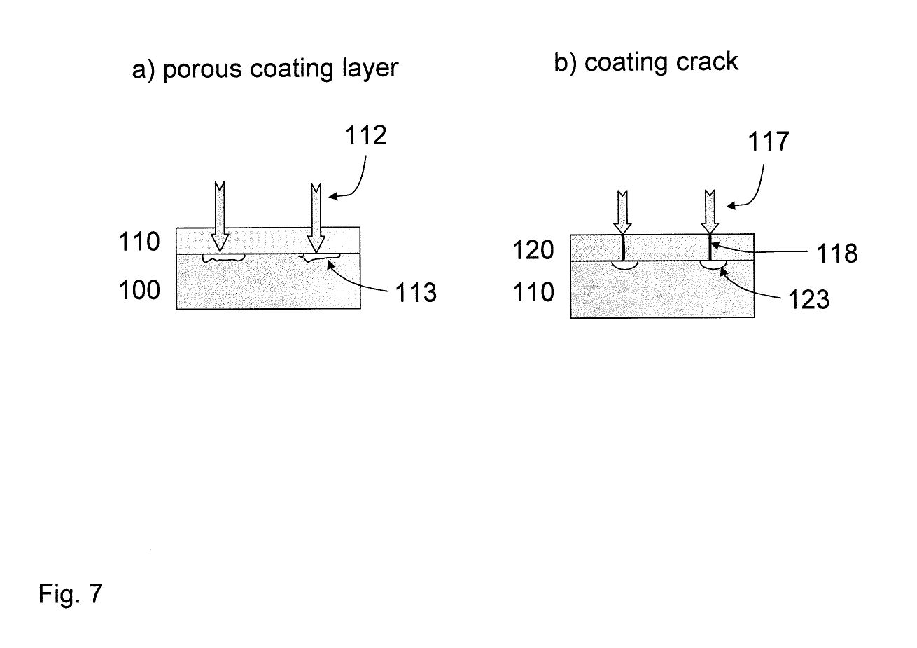

FIG. 7 shows the schematic drawing of bad coating examples with porous coating layer or cracked coating layer. When the coating layer is porous, the etching gas 112 may penetrate through the porous coating layer 110, and then the substrate 100 is partially etched. The porous coating layer 110 would no more adhere to the substrate 100 and the coating layer begins to delaminate and leave etched voids 113 even though the adhesion after the coating was good. The porous coating layer can be detected even though it is exposed to plasma etching for a short time.

On the other hand, even though the coating layer is very dense the coating layer may be cracked when the coating is too thick or too much stress is accumulated on the coating interface. If the coating layer 120 had some deep cracks 118 that reached the substrate, the etching gas 117 would penetrate through the cracks 118 and then the substrate 110 would be etched leaving voids 123. Consequently, the coating layer would have begun to delaminate from the substrate. Such cracks may be avoided or eliminated by optimizing the coating conditions.

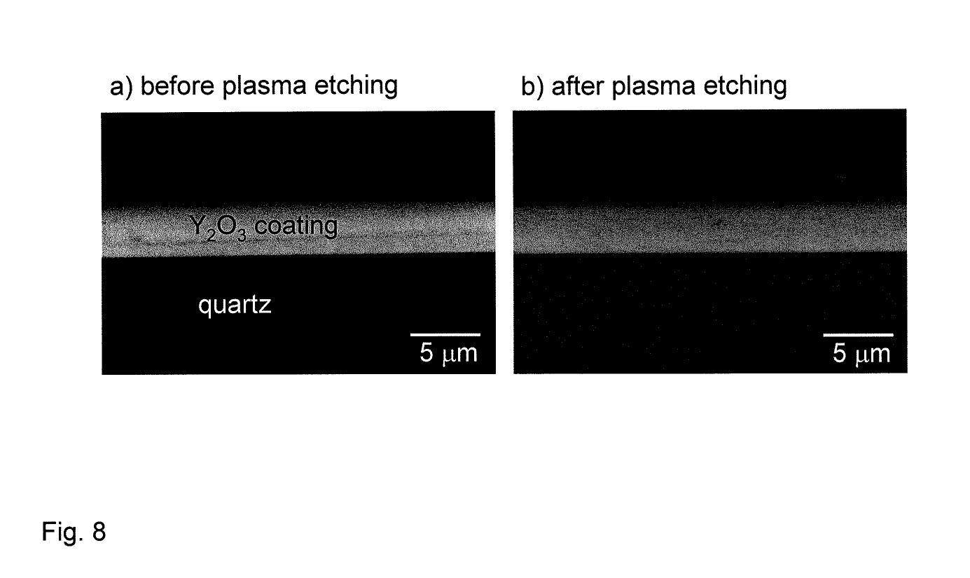

FIG. 8 shows typical cross section of the yttria coated on quartz in this invention before and after plasma etching. The plasma etching condition was 35 sccm of NF₃, 3 sccm of O₂, 500 mTorr and 350 watt direct plasma for 8 h. No appreciable etching was observed and the substrate is not attacked by NF₃ throughout the specimen.

### Example I

Quartz disc made of fused quartz (500 mm diameter×50 mm thick) to be used for 300 mm wafer plasma etching chamber was prepared used as a coating substrate. The disc was ultrasonically cleaned with isopropyl alcohol. Then the disc was installed in electron beam coating chamber and remained under vacuum overnight. The coating chamber vacuum level was kept at 2.4×10⁻⁵ torr and preheated to 200° C. for 1 h. High purity yttria target (>99.99%) was evaporated by electron beam and coated for 5 h to obtain a 5 micron coating thickness. Argon ion beam was used to assist electron beam coating. After the coating, the sample was etching tested in SF₆ for 10 h. No particulation or etching was observed. The etching rate was measured from the difference in coating thickness between plasma exposed area and masked area. The specimen was partially masked with monolithic yttria ceramics. After the plasma etching experiment, the difference in height was measured with surface profilometer. The measured etching rate of yttria-coated sample was below 3 nm/h.

### Example II

A silicon focus ring (360 mm diameter×3.4 mm thick) was used to make an yttria coating. The substrate was ultrasonically cleaned with isopropyl alcohol. Then the ring was cut into small pieces and partially coated in the same way mentioned in Example 1. The coating thickness was 7 micron at the top surface and 3-5 micron at the edge. The focus ring was exposed direct NF₃ plasma (35 sccm NF₃, 3 sccm O₂, 500 mTorr and 350 watt) for 2 h.

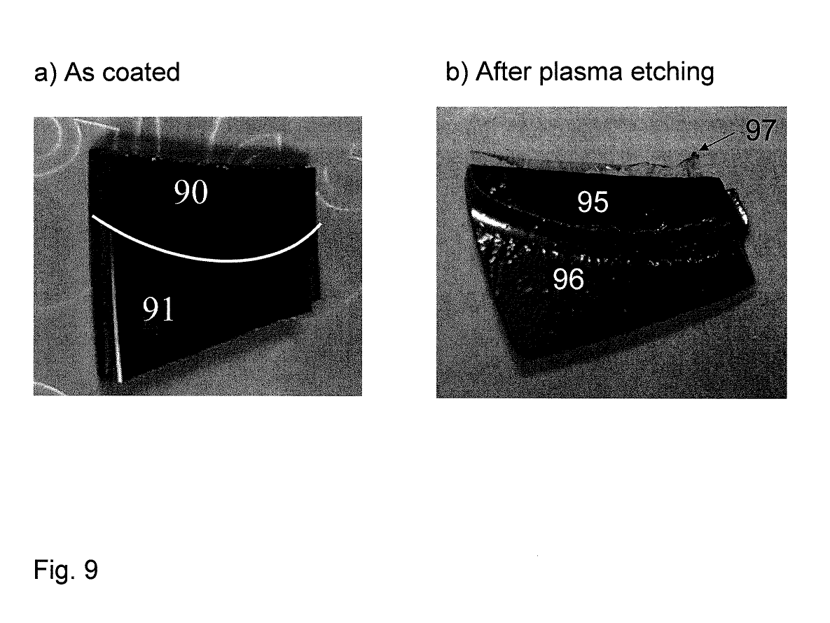

FIG. 9 shows the typical example of partially coated silicon focus ring. As coated specimen shows the difference in contrast. The coated region 90 is slightly darker than uncoated region 91. The boundary was shown with a curved line. After 2 h etching, the coated region 95 is not etched at all, but the uncoated region 96 is etched 1.5 mm deep. The silicon focus ring was attacked from uncoated side as well. Yttria film 97 is still observed to remain on the surface of silicon ring. The underneath portion was etched away.

### Example III

An aluminum coupon (30×30×3 mm), were used to make an yttria coating. The substrate was coated in the same way mentioned in Example 1. The coating thickness was 5 micron. The coated sample was plasma etch tested in direct NF₃ plasma. The etching condition was 35 sccm of NF₃, 3 sccm of O₂, 500 mTorr and 350 watt plasma power. The sample was etched for 8 h. No damage on the coating surface was observed after plasma etching. The etched sample was cross cut and the coating thickness measured by SEM was compared with the sample before plasma etching. The etching rate was less than 3 nm/h in case of the coating on aluminum metal.

### Example IV

Sapphire coupon (25×25×3 mm) was coated with Y₂O₃ coating layer by electron beam coating. The substrate was coated in the same way mentioned in Example I. The coating thickness was 5 micron. The coated sample was plasma etch tested in direct NF₃ plasma. The etching condition was 35 sccm of NF₃, 3 sccm of O₂, 500 mTorr and 350 watt plasma power. The sample was etched for 72 h. Some part of the coating was masked with yttria ceramics to measure the difference of step height between coated area and masked area. The measured etching rate was below 0.5 nm/hour.

### Example V

Quartz coupon (25×25×10 mm) was coated with Y₂O₃ coating layer with Si buffer layer. The buffer layer was first coated by electron beam coating method into ˜0.5 micron thickness and then 4 micron yttria was coated on the buffer layer. The buffer layer would work to decrease the residual stress. The sample was heat treated to 300° C. and held for 2 h and then cooled down. The coating did not peel off after thermal cycle test by Permacel tape test specified in ASTM D3359-09, which is incorporated herein by reference, was carried out. After the coating, the coating color was dark brown because of the silicon coating layer. The sample was plasma etched with NF₃, and no etching was observed by SEM. Surface still shows the yttria peak by EDS.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A method of coating a substrate with a plasma etch-resistant layer that exhibits reduced particulation comprising applying a coating layer to a substrate, wherein coating layer has a thickness of about 20 microns or less.

2. The method of claim 1, wherein the coating layer, after exposure to a fluorine based plasma for an amount of time, is substantially free of any cracks or fissures that span the cross section of the coating layer.

3. The method of claim 2, wherein the amount of time is about 1 to about 5 hours.

4. The method of claim 2, wherein the amount of time is about 1 to about 10 hours.

5. The method of claim 2, wherein the amount of time is about 1 to about 1,000 hours.

6. The method of claim 1, wherein the substrate is chosen from quartz, silicon, alumina, aluminum, anodized aluminum, silicon nitride, silicon carbide, zirconia, SiAlON, AlON, and ceramic composite.

7. The method of claim 1, wherein the coating layer comprises yttria, yttrium aluminum garnet (YAG), yttrium fluoride, and yttrium aluminum perovskite (YAP).

8. The method of claim 1, wherein the coating layer comprises alumina, lanthanum oxide, neodymium oxide, aluminum nitride, silicon nitride, titanium oxide and tantalum oxide with thermal expansion coefficient of about 3×10⁻⁶/° C. to about 20×10⁻⁶/° C.

9. The method of claim 1, wherein the coating layer has a thickness of about 10 microns or less.

10. The method of claim 1, wherein the coating layer has a thickness of about 5 microns or less.

11. The method of claim 1, wherein the coating layer is coated on the substrate by a process selected from electron beam coating, sputtering, physical vapor deposition, chemical vapor deposition, electron beam coating, ion beam, electron beam coating assisted by ion beam.

12. The method of claim 1, wherein the coating layer is coated on the substrate by electron beam coating process conducted under about 700° C.

13. The method of claim 1, further comprising coating the substrate with a buffer layer prior to coating the substrate with the coating layer.

14. The method of claim 13, wherein the buffer layer has a thickness of about 0.1 to about 2 microns.

15. The method of claim 13, wherein the buffer layer has a thermal expansion coefficient that is: (i) less than a thermal expansion coefficient of the coating layer and (ii) greater than a thermal expansion coefficient of the substrate.

16. The method of claim 1, wherein the coating layer exhibits an in-line transmittance greater than about 30% at a wavelength greater than about 300 nm.

17. The method of claim 1, wherein the substrate is in the form of at least portion of a structural element used in a fluorine-based semiconductor wafer processing protocol.

18. The method of claim 17, wherein the element is chosen from a dispersion disc, a chamber wall, a chamber floor, an insulator, an electrostatic chuck, a window, a screw, a bolt, a fastener, a shower head, a heater block, an anodized heater block, a focus ring, an inner ring, an outer ring, a capture ring and an insert ring.

19. A coated substrate prepared by the method of claim 1.

20. A coated substrate for use as a structural element in a fluorine-based semiconductor wafer processing protocol, wherein the coating is a coating layer having a thickness of about 20 microns or less and wherein the coating layer, after exposure to a fluorine based plasma exhibits reduced particulation.

21. The coated substrate of claim 20, wherein the coating layer, after exposure to a fluorine based plasma for an amount of time, is substantially free of any cracks or fissures that span the cross section of the coating layer and exhibits reduced particulation.

22. The coated substrate of claim 20, wherein the amount of time is about 1 to about 5 hours.

23. The coated substrate of claim 20, wherein the amount of time is about 1 to about 10 hours.

24. The coated substrate of claim 20, wherein the amount of time is about 1 to about 1000 hours.

25. The coated substrate of claim 20, wherein the substrate is chosen from quartz, silicon, alumina, aluminum, anodized aluminum, silicon nitride, silicon carbide, zirconia, SiAlON, AlON, and ceramic composite.

26. The coated substrate of claim 20, wherein the coating layer comprises yttria, yttrium aluminum garnet (YAG), yttrium fluoride, and yttrium aluminum perovskite (YAP).

27. The coated substrate of claim 20, wherein the coating layer comprise alumina, lanthanum oxide, neodymium oxide, aluminum nitride, silicon nitride, titanium oxide and tantalum oxide with thermal expansion coefficient of about 3×10⁻⁶/° C. to about 20×10⁻⁶/° C.

28. The coated substrate of claim 20, wherein the coating layer has a thickness of about 15 microns or less.

29. The coated substrate of claim 20, wherein the coating is applied by a process selected from electron beam coating, sputtering, physical vapor deposition, chemical vapor deposition, electron beam coating, ion beam coating, electron beam coating assisted by ion beam.

30. The coated substrate of claim 20, wherein the coating layer is coated on the substrate by electron beam coating process conducted under about 700° C.

31. The coated substrate of claim 20, further comprising a buffer layer.

32. The coated substrate of claim 20, wherein the buffer layer has a thermal expansion coefficient that is: (i) less than a thermal expansion coefficient of the coating layer and (i) greater than a thermal expansion coefficient of the substrate.

33. The coated substrate of claim 20, wherein the coating layer exhibits an in-line transmittance greater than about 30% at a wavelength greater than about 300 nm.

34. A structural element used in a fluorine-based semiconductor wafer processing protocol, wherein at least a portion of a surface of a structural element is coated with a coating layer that having a thickness of about 20 microns or less and wherein the coating layer exhibits reduced particulation after exposure to a fluorine based plasma.

35. The structural element of claim 34, wherein the coating layer, after exposure to a fluorine based plasma for an amount of time, is substantially free of any cracks or fissures that span the cross section of the coating layer and exhibits reduced particulation.

36. The structural element of claim 34, wherein the amount of time is about 1 to about 5 hours.

37. The structural element of claim 34, wherein the amount of time is about 1 to about 10 hours.

38. The structural element of claim 34, wherein the amount of time is about 1 to about 1000 hours.

39. The structural element of claim 34, wherein the substrate is chosen from quartz, silicon, alumina, aluminum, anodized aluminum, silicon nitride, silicon carbide, zirconia, SiAlON, AlON, and ceramic composite.

40. The structural element of claim 34, wherein the coating layer comprises yttria, yttrium aluminum garnet (YAG), yttrium fluoride, and yttrium aluminum perovskite (YAP).

41. The structural element of claim 3, wherein the coating layer comprise alumina, lanthanum oxide, neodymium oxide, aluminum nitride, silicon nitride, titanium oxide and tantalum oxide with thermal expansion coefficient of about 3×10⁻⁶/° C. to about 20×10⁻⁶/° C.

42. The structural element of claim 34, further comprising a buffer layer.

43. The structural element of claim 34, wherein the buffer layer has a thermal expansion coefficient that is: (i) less than a thermal expansion coefficient of the coating layer and (i) greater than a thermal expansion coefficient of the substrate.

44. The structural element of claim 34, wherein the element is chosen from a dispersion disc, a chamber wall, a chamber floor, an insulator, an electrostatic chuck, a window, a screw, a bolt, a fastener, a shower head, a heater block, an anodized heater block, a focus ring, an inner ring, an outer ring, a capture ring and an insert ring.

45. A plasma etch resistant window for use in a semiconductor wafer processing apparatus comprising substrate that is coated with a coating layer wherein the coating layer has a thickness of about 20 microns or less and the coating exhibits an in-line transmittance greater than about 30% at a wavelength greater than about 300 nm.

46. The window of claim 45, wherein the in-line transmittance is greater than about 50% at a wavelength greater than about 400 nm.

47. The window of claim 45, wherein the substrate is quartz.

48. The window of claim 45, wherein the coating layer comprises yttria, yttrium aluminum garnet (YAG), yttrium fluoride, and yttrium aluminum perovskite (YAP).

49. The method of claim 45, wherein the coating layer comprises alumina, lanthanum oxide, neodymium oxide, aluminum nitride, silicon nitride, titanium oxide and tantalum oxide with thermal expansion coefficient of about 3×10⁻⁶/° C. to about 20×10⁻⁶/° C.
